(19) United States
(12) Patent Application Publication
(10) Pub. No.: US 2025/0151200 A1
(43) Pub. Date: May 8, 2025

(54) WIRING BOARD, ELECTRONIC COMPONENT MOUNTING PACKAGE USING WIRING BOARD, AND ELECTRONIC MODULE

(71) Applicant: KYOCERA Corporation, Kyoto-shi, Kyoto (JP)

(72) Inventor: Yoshiki KAWAZU, Omihachiman-shi (JP)

(73) Assignee: KYOCERA Corporation, Kyoto-shi, Kyoto (JP)

(21) Appl. No.: 18/832,975

(22) PCT Filed: Jan. 20, 2023
(86) PCT No.: PCT/JP2023/001745

§ 371 Date: Jul. 25, 2024

(30) Foreign Application Priority Data
Jan. 28, 2022 (JP) 2022-012043

(51) Int. Cl. H05K 1/18; H05K 1/02; H05K 1/11

(52) U.S. Cl. CPC H05K 1/181; H05K 1/0213; H05K 1/111

(57) ABSTRACT

In an embodiment of the present disclosure, a wiring board includes a first insulating layer, a second insulating layer, a signal line, and a first ground conductor line. The first insulating layer includes a first upper surface and a first lower surface. The second insulating layer is positioned on the first insulating layer and includes a second upper surface, a second lower surface, and one or more first opening parts each including an opening at the second upper surface. The signal line is positioned on the second upper surface. The first ground conductor line is positioned on the second upper surface and extends along the signal line with a first gap between the signal line and first ground conductor line. In plan view, at least one first opening part is positioned between the signal line and first ground conductor line and is in contact with the first ground conductor line.

### TECHNICAL FIELD

The present disclosure relates to a wiring board, an electronic component mounting package using a wiring board, and an electronic module.

### BACKGROUND OF INVENTION

In recent years, wireless communication devices and optical communication devices have been required to operate at a higher frequency in order to increase speed and to transmit a large amount of information. Specifically, a known structure to transmit a single-ended signal includes a wiring board including a coplanar structure using a single signal line (see Patent Literature 1).

### CITATION LIST

### Patent Literature

Patent Literature 1: Japanese Unexamined Patent Application Publication No. 2016-181542

### SUMMARY

In an embodiment of the present disclosure, a wiring board includes a first insulating layer, a second insulating layer, a signal line, and a first ground conductor line. The first insulating layer includes a first upper surface and a first lower surface. The second insulating layer is positioned on the first insulating layer and includes a second upper surface, a second lower surface, and one or more first opening parts, each of the first opening parts including an opening at the second upper surface. The signal line is positioned on the second upper surface. The first ground conductor line is positioned on the second upper surface and extends along the signal line with a first gap between the signal line and the first ground conductor line. When seen in plan view, at least one of the one or more first opening parts is positioned between the signal line and the first ground conductor line and is in contact with the first ground conductor line.

In an embodiment of the present disclosure, an electronic component mounting package includes the wiring board, a substrate, and a frame body. The wiring board includes the configuration described above. The frame body is bonded to an upper surface of the substrate.

In an embodiment of the present disclosure, an electronic module includes the electronic component mounting package, an electronic component, and a lid body. The electronic component mounting package includes the configuration described above. The electronic component is positioned on the upper surface of the substrate and electrically connected to the wiring board. The lid body is positioned on the frame body and covers an internal portion of the electronic component mounting package.

### BRIEF DESCRIPTION OF THE DRAWINGS

FIG. 1 is a perspective view of a wiring board, an electronic component mounting package, and an electronic module according to a first embodiment of the present disclosure.

FIG. 2 is an enlarged view of a part A of interest of the wiring board illustrated in FIG. 1.

FIG. 3 is a plan view of the part A of interest of the wiring board illustrated in FIG. 1.

FIG. 4 is a sectional view taken along line X1-X1 of the part A of interest of the wiring board illustrated in FIG. 3.

FIG. 5 is a plan view of a part A of interest of a wiring board according to a second embodiment of the present disclosure.

FIG. 6 is a sectional view taken along line X2-X2 of the part A of interest of the wiring board illustrated in FIG. 5.

FIG. 7 is a schematic perspective view of the electronic component mounting package and the electronic module according to the first embodiment, where an external substrate is connected to the electronic component mounting package and the electronic module.

FIG. 8 is a planar transparent view of a part B of interest of a wiring board illustrated in FIG. 7.

FIG. 9A is a plan view of the external substrate.

FIG. 9B is a plan view of the external substrate when seen from a backside.

FIG. 9C is a sectional view taken along line Y1-Y1 of the part B of interest of the wiring board illustrated in FIG. 8.

### DESCRIPTION OF EMBODIMENTS

### <Wiring Board Configuration>

Hereinafter, several exemplary embodiments of the present disclosure are described with reference to the drawings. Note that any direction may be defined as an upper direction or a lower direction regarding each of a wiring board, an electronic component mounting package using a wiring board, and an electronic module. However, for convenience, an orthogonal coordinate system xyz is defined, and a positive side in a z-direction is assumed as the upper direction. Below, a direction in which a signal line extends indicates, for example, an x-direction in the drawings. A direction orthogonal to the direction in which the signal line extends indicates, for example, a y-direction in the drawings. In the present disclosure, a plan view is a concept including a planar transparent view.

### First Embodiment

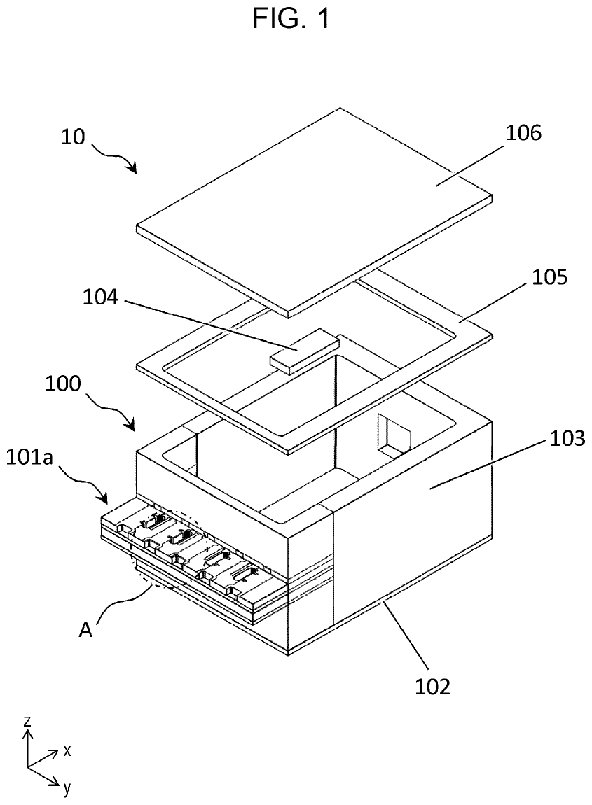

In a first embodiment of the present disclosure, a wiring board 101a is described with reference to FIGS. 1 to 4. The wiring board 101a includes at least a first insulating layer 1, a second insulating layer 2, a signal line 53, and a first ground conductor line 51. The wiring board 101a may further include a second ground conductor line 52, a third insulating layer 3, and a ground conductor layer 6. An external substrate 8, such as flexible printed circuits (FPC), may be connected to the wiring board 101a.

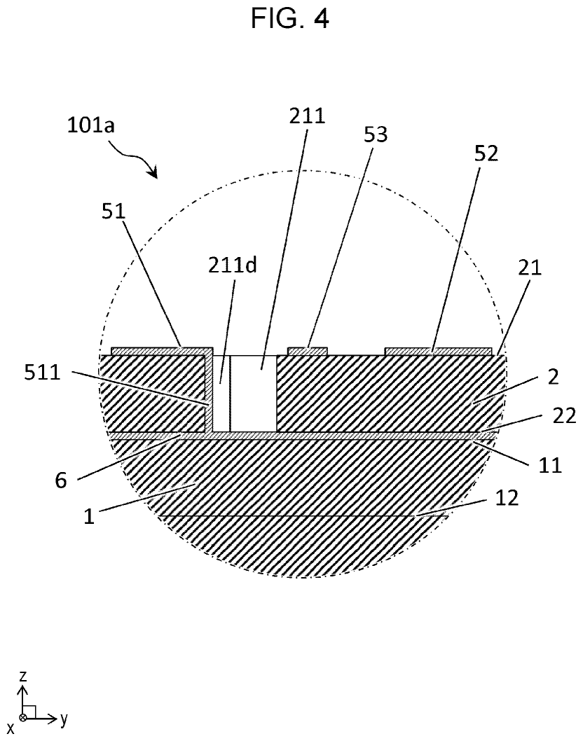

As illustrated in FIG. 4, the first insulating layer 1 includes a first upper surface 11 and a first lower surface 12. As a material for the first insulating layer 1, for example, a dielectric material, such as a ceramic material, for example, an aluminum oxide-based sintered body, a mullite-based sintered body, a silicon carbide-based sintered body, an aluminum nitride-based sintered body, or a silicon nitride-based sintered body, or a glass-ceramic material can be used.

The first insulating layer 1 may include a configuration in which multiple insulating layers are laminated on one another. For example, the first insulating layer 1 has a rectangular shape in plan view, a size of 4 mm×4 mm to 50 mm×50 mm, and a thickness of 0.5 mm to 10 mm.

As illustrated in FIG. 4, the second insulating layer 2 includes a second upper surface 21, a second lower surface 22, and one or more first opening parts 211. Each of the one or more opening parts 211 includes an opening at the second upper surface 21. The second insulating layer 2 is positioned on the first insulating layer 1. A material for the second insulating layer 2 may be the same as or different from the material for the first insulating layer 1, and for example, a material the same as and/or similar to the material for the first insulating layer 1 described above can be used. The second insulating layer 2 may include a configuration in which multiple insulating layers are laminated on one another. For example, the second insulating layer 2 has a rectangular shape in plan view, a size of 4 mm×4 mm to 50 mm×50 mm, and a thickness of 0.5 mm to 10 mm.

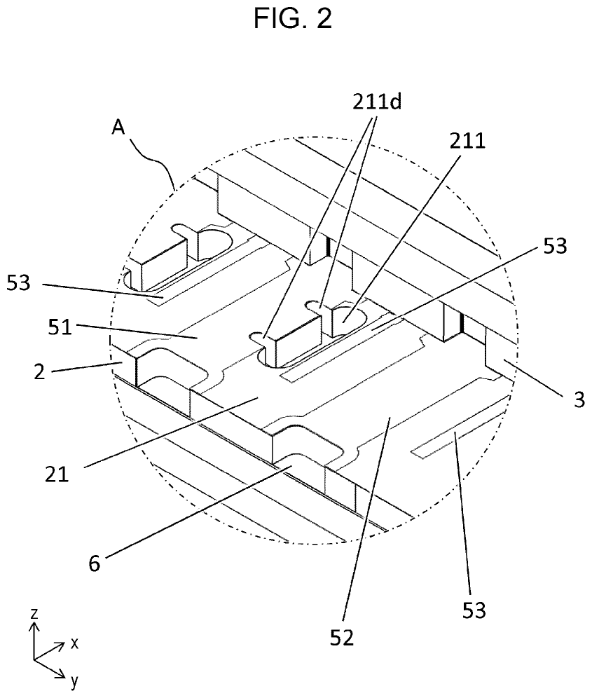

As illustrated in FIGS. 2 to 4, the signal line 53 is positioned on the second upper surface 21 of the second insulating layer 2 and, in this embodiment, extends in the x-direction. Below, a direction in which the signal line extends is the x-direction, and a direction orthogonal to the direction in which the signal line extends is the y-direction. Examples of a material for the signal line 53 include a metal material, such as gold, silver, copper, nickel, tungsten, molybdenum, or manganese. The signal line 53 may be formed by sintering of metal paste on the second upper surface 21, or formed by using a thin-film formation technology, such as a vapor deposition method or a spattering method. Metal plating, such as nickel plating or gold plating may be formed on a surface of the signal line 53. For example, the signal line 53 has a width of 0.05 mm to 2 mm and a length of 1.5 mm to 25 mm. For example, the signal line 53 has a thickness of 0.01 to 0.1 mm. Note that the width, length, and thickness of the signal line 53 as used herein can indicate a y-direction dimension, an x-direction dimension, and a z-direction dimension of the signal line 53, respectively. A width/length/thickness of each of the first ground conductor line 51, the second ground conductor line 52, and a third ground conductor line 83 described later can also be defined in the same and/or similar manner.

As illustrated in FIGS. 2 to 4, the first ground conductor line 51 is positioned on the second upper surface 21 of the second insulating layer 2 and extends along the signal line 53 with a first gap L1 between the signal line 53 and the first ground conductor line 51 in the y-direction. In this embodiment, the first ground conductor line 51 extends in parallel to the signal line 53 and extends in the x-direction. A material for the first ground conductor line 51 may be the same as or different from the material for the signal line 53 and include, for example, a material the same as and/or similar to the material for the signal line 53 described above. The first ground conductor line 51 may be formed in a method the same as and/or similar to that for the signal line 53 described above. For example, the first ground conductor line 51 has a width of 0.05 mm to 2 mm, and a length of 1.5 mm to 25 mm. For example, the first ground conductor line 51 has a thickness of 0.01 mm to 0.1 mm. For example, a dimension of the first gap L1 is 0.1 mm to 1 mm. When the wiring board 101a includes the first ground conductor line 51 and the signal line 53, the wiring board 101a may include a GSG structure, that is, single-ended signal wiring.

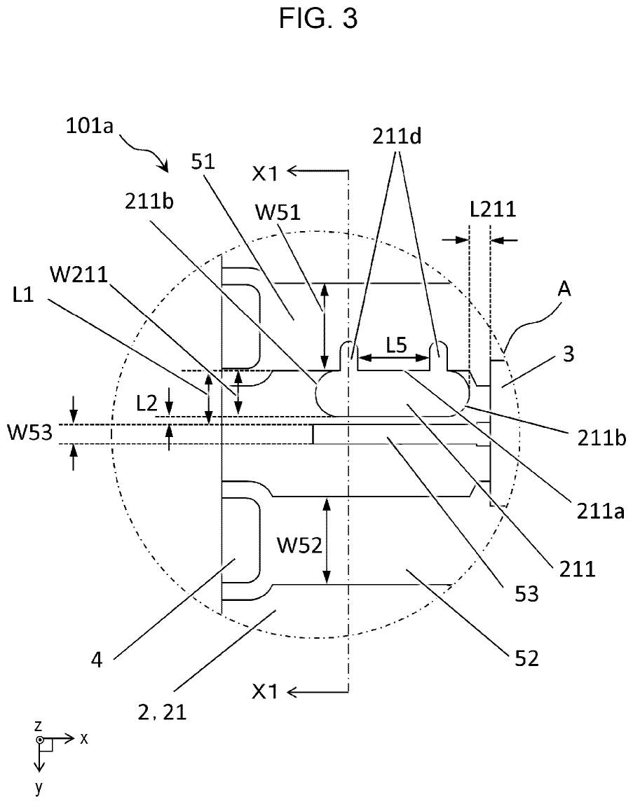

As described above, the second insulating layer 2 includes the first opening part 211 including the opening at the second upper surface 21. As illustrated in FIG. 3, in plan view, at least one of the first opening parts 211 is positioned between the signal line 53 and the first ground conductor line 51 and is in contact with the first ground conductor line 51. The first opening part 211 is filled with air or a dielectric material such as a resin material or a glass material and has lower permittivity than that of the first insulating layer 1 and the second insulating layer 2.

Since the first opening part 211 is in contact with the first ground conductor line 51, the first opening part 211 can be as large as possible. Note that when a lead terminal or the third ground conductor line 83 of the external substrate 8 such as FPC (described later) is bonded onto the first ground conductor line 51 by using a bonding material F, the bonding material F which overflows excessively can escape into the first opening part 211. Therefore, when compared to a case in which the first opening part 211 is not in contact with the first ground conductor line 51, an amount of the bonding material F can be increased, and bonding strength with respect to the lead terminal or the external substrate 8 can improve. The bonding material F may be any material as long as the material electrically connects the lead terminal or the external substrate 8 to the first ground conductor line 51, and may be solder, for example.

Therefore, when the second insulating layer 2 includes the first opening part 211 in contact with the first ground conductor line 51, the second insulating layer 2 positioned between the signal line 53 and the first ground conductor line 51 in plan view and having high permittivity can be reduced, and thereby a decrease in impedance at the signal line 53 can be mitigated. Therefore, using the wiring board 101a can provide an electronic component mounting package and an electronic module capable of reducing loss in transmitting a radio-frequency signal.

When the wiring board 101a is reduced in size, the first gap L1 is narrower, and an impedance value is more likely to decrease. However, the contact between the first opening part 211 and the first ground conductor line 51 allows the first opening part 211 to be as large as possible, and thereby both mitigating a decrease in impedance and reducing the size of the wiring board 101a are achievable.

The first opening part 211 may be positioned with a second gap L2 between the signal line 53 and the first opening part 211 in the y-direction. In this case, when the first opening part 211 is provided to the second insulating layer 2 by, for example, mechanical punching processing using a metal pin, the signal line 53 can be less likely to be damaged due to positional deviation in the punching processing. For example, a dimension of the second gap L2 is 0.01 mm to 0.5 mm.

A shape of the first opening part 211 is described. As illustrated in FIG. 4, the first opening part 211 may pass through from the second upper surface 21 to the second lower surface 22. That is, the first opening part 211 may pass through the second insulating layer 2. As illustrated in FIG. 3, the first opening part 211 may be, for example, an oval-shaped part including a first arc portion 211b, a second arc portion 211c, and a first linear portion 211a. In this case, the first opening part 211 has a width of 0.1 mm to 1 mm, and a z-direction dimension (depth) of 0.5 mm to 10 mm. Although the width and/or depth of the first opening part 211 may not be constant depending on the shape of the first opening part 211, in such a case, a maximum width and/or a maximum depth of the first opening part 211 may be the value described above. When the depth is constant as in this embodiment, ceramic green sheets to be the first insulating layer 1 and the second insulating layer 2 can easily be manufactured by lamination. Note that the first opening part 211 may have an ellipse shape, a square shape, or a rectangular shape with rounded corners in plan view. The first opening part 211 may reach an end portion (end surface) of the second insulating layer 2. That is, the first opening part 211 may have a shape in which the end portion (end surface) of the second insulating layer 2 is cutout.

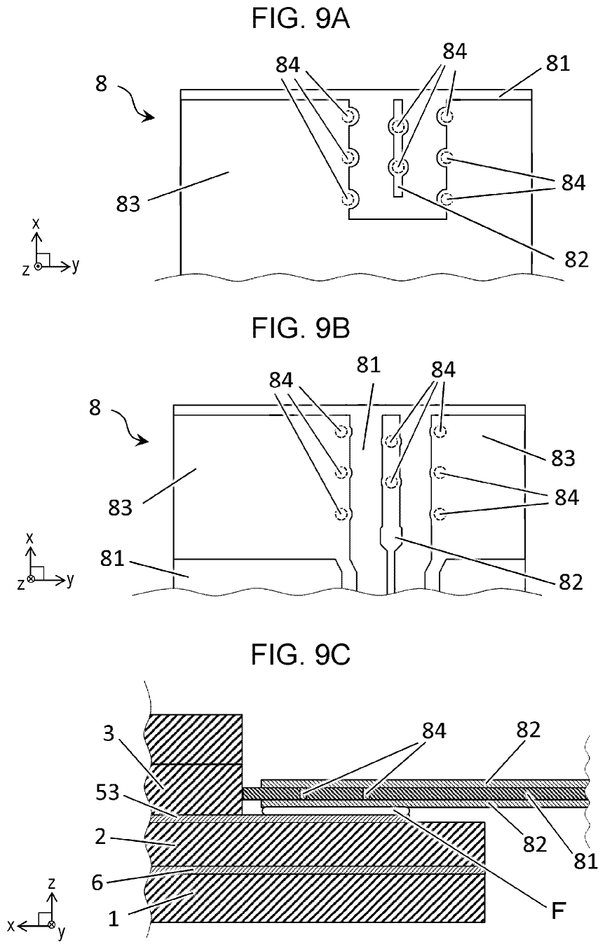

In this embodiment, as illustrated in FIGS. 2 and 3, the third insulating layer 3 may be positioned on the second insulating layer 2. A material for the third insulating layer 3 may be the same as or different from the material for the first insulating layer 1, and for example, a material the same as and/or similar to that for the first insulating layer 1 described above can be used. In this case, the first opening part 211 may be positioned with a sixth gap L211 between the third insulating layer 3 and the first opening part 211 in the x-direction. For example, a dimension of the sixth gap L211 is 0.01 mm to 0.5 mm. When the first opening part 211 is positioned with the sixth gap L211 between the third insulating layer 3 and the first opening part 211, for example, an impedance value is easily adjustable when the signal transmission line 82 of the external substrate 8 illustrated in FIG. 9A (FIG. 9B) or a lead terminal is connected to the signal line 53.

As illustrated in FIGS. 3 and 4, the first opening part 211 may include a first recess portion 211d positioned at an inner circumferential surface of the first opening part 211 and in contact with the first ground conductor line 51. When the first opening part 211 includes the first recess portion 211d, the first ground conductor line 51 may include, on an inner circumferential surface of the first recess portion 211d, a first ground conductor film 511 continuing to the first ground conductor line 51. That is, the first recess portion 211d and the first ground conductor film 511 may serve as a so-called castellation. In this case, a ground potential is reinforced and electric coupling is strengthened, and thereby crosstalk and/or resonance can be less likely to occur. The crosstalk and/or resonance occurs due to spreading of electric field distribution beyond a desired range during transmission of a radio-frequency signal. In this embodiment, the first recess portion 211d has a semi-ellipse shape in plan view. However, the shape of the first recess portion 211d is not limited to this, but may be a square shape or a rectangular shape with rounded corners.

Note that, as illustrated in FIG. 4, in the first opening part 211, the second insulating layer 2 may be exposed at the inner circumferential surface of the first opening part 211 except at the first recess portion 211d. That is, a conductor such as the first ground conductor film 511 may not be provided to the inner circumferential surface of the first opening part 211 except at the first recess portion 211d. Therefore, a decrease in an impedance value between the signal line 53 and the first ground conductor line 51 and an increase in signal loss can be mitigated. When the signal line 53 is provided on the second insulating layer 2 by screen printing or the like, short-circuiting can be less likely to occur even when a part of the signal line 53 is positioned at a part of the inner circumferential surface of the first opening part 211 due to positional deviation. Note that the inner circumferential surface of the first opening part 211 as used herein is a surface perpendicular to the y-direction in this embodiment.

When seen in plan view, the first opening part 211 may include multiple first recess portions 211d positioned with a fifth gap L5 therebetween in the x-direction. The fifth gap L5 may be half or less than half of a signal wavelength λ which is transmitted through the signal line 53. Such a configuration can effectively improve signal transmission characteristics. When the fifth gap L5 is quarter or less than quarter of the signal wavelength λ which is transmitted through the signal line 53, the ground potential is further reinforced, and the signal transmission characteristics can effectively improve.

Note that when the first opening part 211 includes the multiple first recess portions 211d, shapes of the multiple first recess portions 211d may be the same as or different from one another. When the multiple first recess portions 211d have the same shape as one another as in this embodiment, the same metal pin is usable upon providing the first recess portions 211d by mechanical punching processing using a metal pin. Therefore, manufacture of the wiring board 101a can be easy. Note that when the multiple first recess portions 211d have different shapes from one another, a degree of freedom in manufacture improves, and thereby the ground potential can effectively be reinforced at a position on the signal line 53 where an impedance value may decrease.

As described above, when seen in plan view, the first opening part 211 may be an oval-shaped part including the first arc portion 211b, the second arc portion 211c, and the first linear portion 211a. In this case, at least one of the multiple first recess portions 211d may be positioned between the first arc portion 211b and the first linear portion 211a and/or between the second arc portion 211c and the first linear portion 211a. Such a configuration can increase the number of the first recess portions 211d while maintaining the fifth gap L5 even when the wiring board 101a has a reduced size. As a result, the ground potential is further reinforced, and crosstalk and/or resonance can be less likely to occur. The crosstalk and/or resonance occurs due to spreading of electric field distribution beyond a desired range during transmission of a radio-frequency signal.

Sizes of the first ground conductor line 51, the signal line 53, and the first opening part 211, and a positional relationships therebetween are described.

As illustrated in FIG. 3, the second gap L2 may be equal to or less than a width W211 of the first opening part 211 in the y-direction. In this case, the first opening part 211 can be as large as possible while a possibility of damaging the signal line 53 due to positional deviation in punching processing being reduced. As a result, an impedance value is less likely to decrease, and a possibility of signal loss in the signal line 53 can be lower.

The first gap L1 may be equal to or greater than a width W53 of the signal line 53 in the y-direction. In this case, the signal line 53 can have a small width W53, and thereby a decrease in an impedance value upon connecting a lead terminal or the external substrate 8 can be mitigated.

The width W53 of the signal line 53 may be equal to or less than the width W211 of the first opening part 211 in the y-direction.

The width W211 of the first opening part 211 may be greater than the width W53 of the signal line 53 and less than the width W51 of the first ground conductor line 51 in the y-direction. Note that in a case of, for example, not requiring size reduction of the wiring board 101a, the width W51 of the first ground conductor line 51 may be less than the width W211 of the first opening part 211 and greater than the width W53 of the signal line 53. Such a configuration enables the first opening part 211 positioned between the first ground conductor line 51 and the signal line 53 in plan view to be as large as possible even when the first gap L1 is large. In other words, the second insulating layer 2 positioned between the first ground conductor line 51 and the signal line 53 in plan view and having high permittivity can be reduced as much as possible, and thereby mitigation of a decrease in impedance is effectively achievable.

In this embodiment, as described above, the wiring board 101a may further include the second ground conductor line 52 and the ground conductor layer 6.

As illustrated in FIGS. 2 to 4, the second ground conductor line 52 is positioned on the second upper surface 21 of the second insulating layer 2 and extends along the signal line 53 with a third gap L3 between the signal line 53 and the second ground conductor line 52 in the y-direction. A material for the second ground conductor line 52 may be the same as or different from the material for the signal line 53, and include, for example, a material the same as and/or similar to the material for the signal line 53 described above. The second ground conductor line 52 may be formed in a method the same as and/or similar to that for the signal line 53 described above. For example, the second ground conductor line 52 has a width of 0.05 mm to 2 mm, and a length of 1.5 mm to 25 mm. For example, the second ground conductor line 52 has a thickness of 0.01 to 0.1 mm.

When the wiring board 101a includes the second ground conductor line 52, signal transmission loss can be smaller. The loss occurs when wiring such as the signal line 53 or the first ground conductor line 51 has a bent (curved portion). Crosstalk and/or resonance can be less likely to occur. The crosstalk and/or resonance occurs due to spreading of electric field distribution beyond a desired range during transmission of a radio-frequency signal.

The ground conductor layer 6 is positioned between the first insulating layer 1 and the second insulating layer 2. Examples of a material for the ground conductor layer 6 include a metal material, such as tungsten, molybdenum, or manganese, and nickel plating or gold plating may be applied to a surface of the ground conductor layer 6. As illustrated in FIG. 4, the ground conductor layer 6 is exposed at a lower surface of the first opening part 211. When the wiring board 101a includes the ground conductor layer 6, electric coupling can be strengthened, and thereby crosstalk and/or resonance can be less likely to occur. The crosstalk and/or resonance occurs due to spreading of electric field distribution beyond a desired range during transmission of a radio-frequency signal.

The first ground conductor film 511 described above may electrically connect the ground conductor layer 6 to the first ground conductor line 51. In this case, electric coupling can further be strengthened, and thereby crosstalk and/or resonance can effectively be made less likely to occur. The crosstalk and/or resonance occurs due to spreading of electric field distribution beyond a desired range during transmission of a radio-frequency signal.

Although not illustrated, in this embodiment, an insulating film, such as a ceramic (for example, aluminum coat) or a resin may be positioned on a portion of the first ground conductor line 51, a portion of the second ground conductor line 52, and a portion of the signal line 53. The insulating film can be provided onto the first ground conductor line 51 and the signal line 53 by screen printing. The insulating film may be positioned only on the signal line 53. Such a configuration can reduce a possibility of short-circuiting in each of the first ground conductor line 51, the second ground conductor line 52, and the signal line 53.

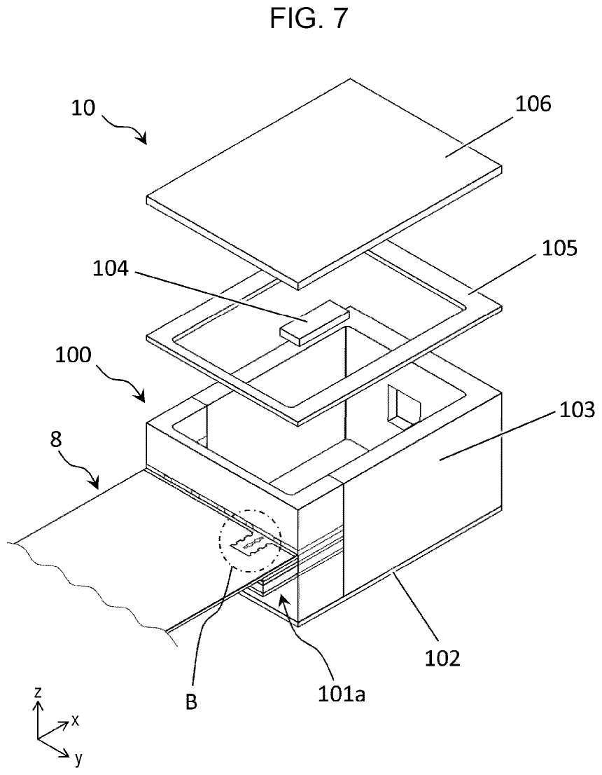

As illustrated in FIG. 7, the external substrate 8 may be connected to the electronic component mounting package 100 including the wiring board 101a. Note that FIG. 7 is a view illustrating a part of the wiring board 101a overlapping the external substrate 8 to be transparent. The external substrate 8 includes an insulating substrate 81, a signal transmission line 82, and a third ground conductor line 83. As illustrated in FIGS. 9A and 9B, the third ground conductor line 83 and the signal transmission line 82 are positioned on the insulating substrate 81, that is, on an upper surface and a lower surface of the insulating substrate 81. More specifically, as illustrated in FIG. 9C, the third ground conductor lines 83 are positioned to sandwich the upper surface and the lower surface of the insulating substrate 81, and a connection conductor 84 electrically connects the third ground conductor lines 83 positioned on the respective ones of the upper surface and on the lower surface. The signal transmission lines 82 are also positioned to sandwich the upper surface and the lower surface of the insulating substrate 81, the same as and/or similarly to the third ground conductor lines 83, and the connection conductor 84 electrically connects the signal transmission lines 82 positioned on the respective ones of the upper surface and on the lower surface. The signal transmission line 82 of the external substrate 8 is connected to the signal line 53 of the wiring board 101a via the bonding material F. In the same and/or similar manner, the third ground conductor line 83 is connected to the first ground conductor line 51 and the second ground conductor line 52 of the wiring board 101a via the bonding material F.

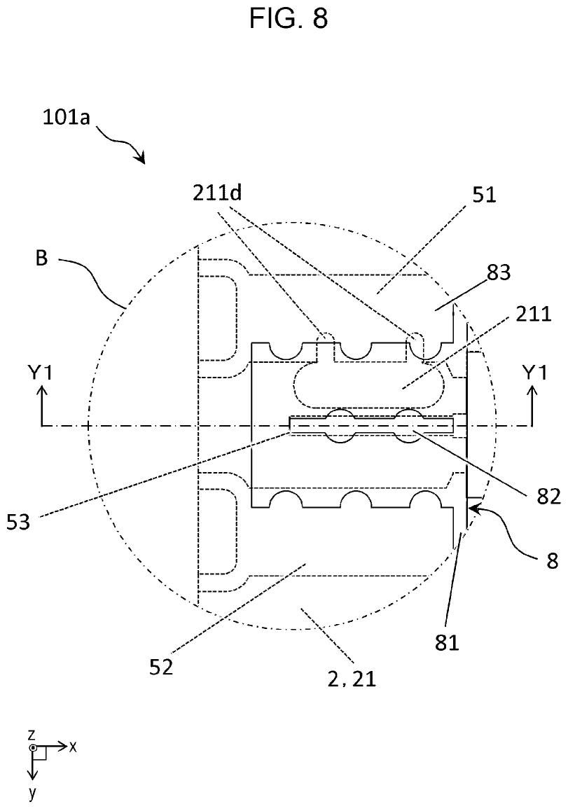

As illustrated in FIG. 8, in plan view, the third ground conductor line 83 overlaps at least a part of the first recess portion 211d. In this case, when a lead terminal or the third ground conductor line 83 of the external substrate 8 such as FPC is bonded onto the first ground conductor line 51 by using the bonding material F, the bonding material F which overflows excessively can escape also into the first recess portion 211d. As a result, bonding strength with respect to the lead terminal and the external substrate 8 can further improve.

As an alternative to the external substrate 8, a lead terminal may be connected to the wiring board 101a. In this case, the lead terminal is connectable to each of the signal line 53, the first ground conductor line 51, and the second ground conductor line 52 via the bonding material F.

### Second Embodiment

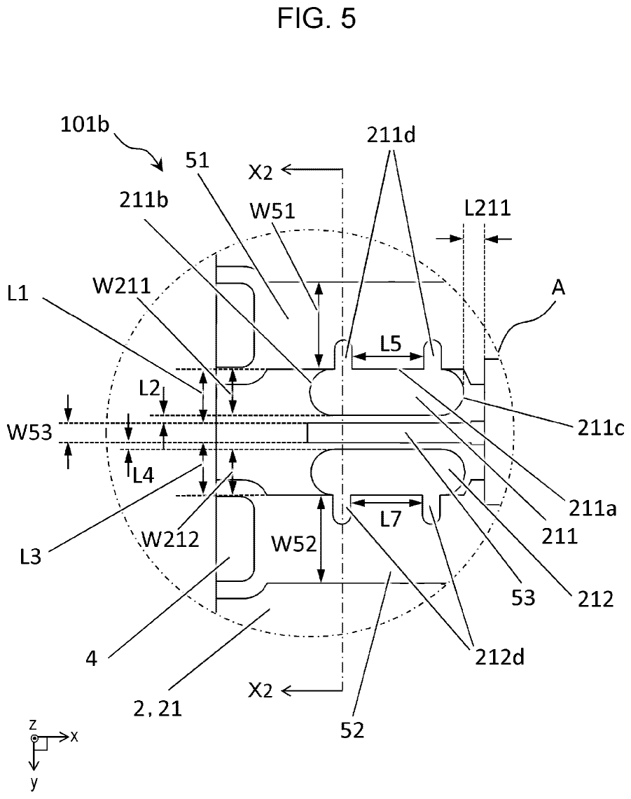

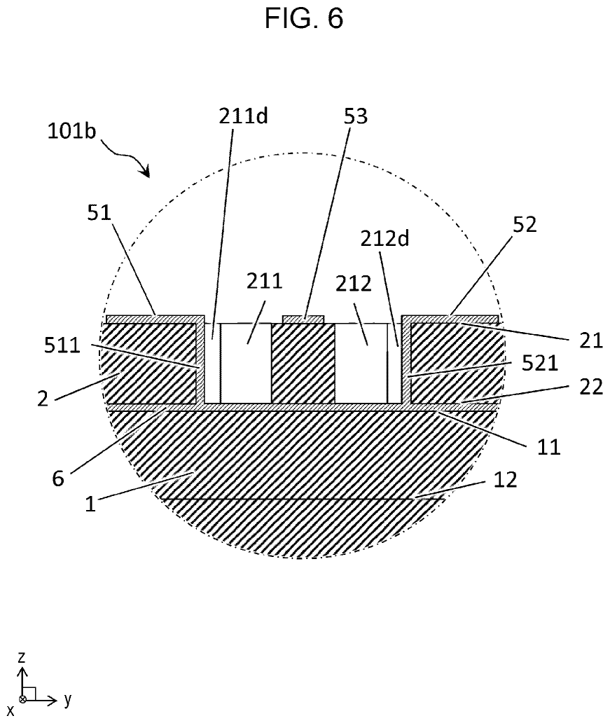

In a second embodiment of the present disclosure, a wiring board 101b is described with reference to FIGS. 5 and 6. Note that, below, among configurations of the second embodiment, only configurations different from the configurations of the first embodiment are described, and configurations other than the different configurations are denoted by reference characters the same as and/or similar to those for the first embodiment to omit description thereof.

In the second embodiment, the wiring board 101b is different from the first embodiment in that the second insulating layer 2 further includes a second opening part 212.

As illustrated in FIGS. 5 and 6, the second insulating layer 2 further includes one or more second opening parts 212. Each of the one or more second opening parts 212 includes an opening at the second upper surface 21. When seen in plan view, at least one of the one or more second opening parts 212 is positioned between the signal line 53 and the second ground conductor line 52 and in contact with the second ground conductor line 52. The second opening part 212 is filled with air or a dielectric material such as a resin material or a glass material and has lower permittivity than that of the first insulating layer 1 and the second insulating layer 2.

Accordingly, when the second insulating layer 2 includes the second opening part 212 in contact with the second ground conductor line 52, effects the same as and/or similar to the case of including the first opening part 211 in contact with the first ground conductor line 51 are achievable. Therefore, using the wiring board 101b can provide an electronic component mounting package and an electronic module capable of reducing loss in transmitting a radio-frequency signal.

The second opening part 212 may be positioned with a fourth gap L4 between the signal line 53 and the second opening part 212 in the y-direction. In this case, when the second opening part 212 is provided to the second insulating layer 2 by, for example, mechanical punching processing using a metal pin, the signal line 53 can be less likely to be damaged due to positional deviation in the punching processing. For example, a dimension of the fourth gap L4 is 0.05 mm to 0.5 mm and may be the same as or different from the second gap L2. When the fourth gap L4 is the same as the second gap L2, thicknesses of portions of the second insulating layer 2, the portions sandwiching the signal line 53 therebetween, in the y-direction are the same as one another, and thereby an impedance value is easily adjustable.

As illustrated in FIG. 6, the second opening part 212 may pass through from the second upper surface 21 to the second lower surface 22. That is, the second opening part 212 may pass through the second insulating layer 2. The second opening part 212 may have a shape the same as and/or similar to that of the first opening part 211. In this case, a width is 0.1 mm to 1 mm, and a z-direction dimension (depth) is 0.5 mm to 10 mm. Note that, the same as and/or similarly to the first opening part 211, the width and/or depth of the second opening part 212 as used here may not be a constant width and/or a constant depth throughout the entire second opening part 212. The second opening part 212 may reach an end portion (end surface) of the second insulating layer 2. That is, the second opening part 212 may have a shape in which the end portion (end surface) of the second insulating layer 2 is cutout.

Note that the second opening part 212 may have an ellipse shape, a square shape, or a rectangular shape with rounded corners in plan view. The second opening part 212 does not necessarily have the same shape or the same size as that of the first opening part 211. Although in this embodiment the second opening part 212 has a symmetrical shape while sandwiching the signal line 53, the shape, the position, and the size of the second opening part 212 are not limited to those described above. That is, the sizes of the first opening part 211 and the second opening part 212 may be different from one another, and the second opening part 212 may suitably be provided at a position at which mitigation of a decrease in impedance is required. When the y-direction and x-direction widths of the first opening part 211 are the same as those of the second opening part 212 as in this embodiment, impedance values at both sides of the signal line 53 can be the same, and thereby the impedance values are easily adjustable.

As illustrated in FIGS. 5 and 6, the second opening part 212 may include a second recess portion 212d, the same as and/or similarly to the first recess portion 211d of the first opening part 211. When the second opening part 212 includes the second recess portion 212d, the second ground conductor line 52 may include, on an inner circumferential surface of the second recess portion 212d, a second ground conductor film 521 continuing to the second ground conductor line 52. In this case, effects the same as and/or similar to the case in which the first opening part 211 includes the first recess portion 211d are achievable. Although in this embodiment the second recess portion 212d has a semi-ellipse shape in plan view, it may have a square shape or a rectangular shape with rounded corners. The shape of the second recess portion 212d may be the same as or different from that of the first recess portion 211d described above.

When seen in plan view, the second opening part 212 may include multiple second recess portions 212d positioned with a seventh gap L7 therebetween in the x-direction. The seventh gap L7 may be half or less than half of the signal wavelength λ which is transmitted through the signal line 53. In such a configuration, effects the same as and/or similar to the case in which the first recess portions 211d are positioned with the fifth gap L5 therebetween are achievable.

When, in plan view, the second opening part 212 is an oval-shaped part including an arc portion and a linear portion, at least one of the multiple second recess portions 212d may be positioned between the arc portion and the linear portion. Effects the same as and/or similar to the case in which the first opening part 211 includes the multiple first recess portions 211d are achievable, for example, when the wiring board 101b has a reduced size.

With respect to the sizes of the second ground conductor line 52, the signal line 53, and the second opening part 212, and the positional relationship therebetween, other than those described above, ones the same as and/or similar to the sizes of the first ground conductor line 51, the signal line 53, and the first opening part 211, and the positional relationship therebetween are adaptable. Therefore, effects the same as and/or similar to those of the first ground conductor line 51, the signal line 53, and the first opening part 211 are achievable. Note that the first gap L1 may be read as the third gap L3, and the second gap L2 may be read as the fourth gap L4.

### <Method for Manufacturing Wiring Board>

In the first embodiment of the present disclosure, a method for manufacturing the wiring board 101a is described. Note that the method for manufacturing the wiring board 101a according to the embodiment of the present disclosure is not limited to the embodiment described below, but may use a 3D printer to manufacture the wiring board 101a.
(1) First, a plurality of green sheets is formed. Specifically, for example, a mixture is obtained by adding and mixing organic binder, plasticizer, a solvent, or the like to ceramic powder, such as boron nitride, aluminum nitride, silicon nitride, silicon carbide, beryllium oxide, or the like. Then, the mixture is formed to be layered to fabricate multiple green sheets. Next, the multiple green sheets are processed using a die or the like to prepare the multiple green sheets formed to have respective external shapes of the first insulating layer 1 and the second insulating layer 2 in plan view. In a case of forming the wiring board 101a including the third insulating layer 3, a green sheet formed to have an external shape of the third insulating layer 3 is additionally prepared. Next, the first opening part 211 is provided, by using a die, a laser, or the like, to the green sheet which becomes the second insulating layer 2. Note that in a case of forming the wiring board 101a including the first recess portion 211d, the same as and/or similarly to the first opening part 211, the first recess portion 211d is provided to the green sheet which becomes the second insulating layer 2. When the second insulating layer 2 includes the second opening part 212 as in the second embodiment, the second opening part 212 may be provided in the same and/or similar manner as that for the first opening part 211.
(2) High-melting-point metal powder such as tungsten or molybdenum is prepared, and metal paste is prepared by adding and mixing organic binder, plasticizer, a solvent, or the like to the prepared powder. Next, the metal paste is printed in a given pattern on the multiple green sheets formed to have the respective external shapes of the first insulating layer 1, the second insulating layer 2, and the third insulating layer 3, to form the signal line 53, the first ground conductor line 51, and the second ground conductor line 52. Note that the metal paste may include glass or ceramics to increase bonding strength with respect to each insulating layer. The first ground conductor film 511 can be formed by printing the metal paste at the first recess portion 211d created in the above-described process.
(3) Next, a method for making the ground conductor layer 6 is described. For example, when the ground conductor layer 6 is a metalized layer made of metal with a high melting point, such as tungsten, molybdenum, or manganese, the ground conductor layer 6 can be formed as follows. That is, first, metal paste is made by kneading metal powder having a high melting point, together with an organic solvent and binder to be well mixed up. Then, the metal paste is printed, in a method such as screen printing, at a given position of the ceramic green sheet. The given position is to be the second lower surface 22 of the second insulating layer 2 or the first upper surface 11 of the first insulating layer 1.
(4) The multiple green sheets formed to have the respective external shapes of the first insulating layer 1 and the second insulating layer 2, and the ground conductor layer 6 are stacked on one another in such a manner that outer edge portions of the multiple green sheets match an outer edge portion of the ground conductor layer 6. Thereby, a green sheet stacking body is formed. Note that after the formation of the green sheet stacking body, metal paste may be printed in a given pattern to form the first ground conductor line 51, the second ground conductor line 52, the signal line 53, and another wiring line.
(5) The green sheet stacking body is fired to sinter the multiple green sheets, thus obtaining the wiring board 101a.

### <Configuration of Electronic Component Mounting Package>

As illustrated in FIG. 1, in this embodiment, the electronic component mounting package 100 includes the wiring board 101a, a substrate 102, and a frame body 103. The frame body 103 is bonded to an upper surface of the substrate 102, and the wiring board 101a is fixed to the frame body 103. The wiring board 101a may be bonded to the upper surface of the substrate 102.

The substrate 102 includes the upper surface. For example, the substrate 102 has a quadrilateral shape in plan view, a size of 10 mm×10 mm to 50 mm×50 mm, and a thickness of 0.5 mm to 20 mm. Examples of a material for the substrate 102 include a metal material, such as copper, iron, tungsten, molybdenum, nickel, or cobalt, or an alloy containing these metal materials. In this case, the substrate 102 may be a single metal plate or a multilayer body including a plurality of laminated metal plates. When the material for the substrate 102 is the metal material described above, in order to reduce oxidation corrosion, a surface of the substrate 102 may be formed with a plating layer of nickel, gold, or the like, by using an electroplating method or an electroless plating method. A material for the substrate 102 may be an insulating material, for example, a ceramic material, such as an aluminum oxide-based sintered body, a mullite-based sintered body, a silicon carbide-based sintered body, an aluminum nitride-based sintered body, a silicon nitride-based sintered body, or glass ceramics.

The frame body 103 is positioned on the upper surface of the substrate 102 and protects an electronic component 104 positioned inside in plan view. That is, the frame body 103 surrounds the electronic component 104 when seen in plan view. As illustrated in FIG. 1, in this embodiment, the frame body 103 is not positioned at one side of an outer edge of the upper surface of the substrate 102. That is, the frame body 103 and the wiring board 101a surround the outer edge of the upper surface of the substrate 102. That is, the frame body 103 and the wiring board 101a surround the electronic component 104. In this manner, the frame body 103 does not necessarily surround the entirety of the outer edge of the upper surface of the substrate 102. Although in this embodiment the frame body 103 is positioned along the outer edge of the upper surface of the substrate 102, it may be positioned at an inner side of the outer edge of the upper surface of the substrate 102.

A material for the frame body 103 may be, for example, a metal material, such as copper, iron, tungsten, molybdenum, nickel, or cobalt, or an alloy containing these metal materials. The material for the frame body 103 may be an insulating material, for example, a ceramic material, such as an aluminum oxide-based sintered body, a mullite-based sintered body, a silicon carbide-based sintered body, an aluminum nitride-based sintered body, a silicon nitride-based sintered body, or glass ceramics.

The frame body 103 may be bonded to the substrate 102 with a brazing material or the like interposed therebetween. Note that a material of the brazing material is, for example, silver, copper, gold, aluminum, or magnesium, and may contain an additive such as nickel, cadmium, or phosphorus.

### <Configuration of Electronic Module>

As illustrated in FIG. 1, the electronic module 10 includes the electronic component mounting package 100, the electronic component 104, and a lid body 106. The electronic module 10 may include a seal ring 105.

The electronic component 104 may be, for example, a component which performs signal processing, such as conversion of an optical signal into an electrical signal, or conversion of an electrical signal into an optical signal. The electronic component 104 is positioned on the upper surface of the substrate 102 and is accommodated in the electronic component mounting package 100.

Examples of the electronic component 104 include an optical semiconductor element, such as a semiconductor laser (LD: laser diode) or a photo diode (PD), a semiconductor integrated circuit element, and a sensor element such as an optical sensor. For example, the electronic component 104 can be formed by using a semiconductor material, such as gallium arsenide or gallium nitride.

The lid body 106 is positioned on the frame body 103 to cover an internal portion of the electronic component mounting package 100, and protects, together with the frame body 103, the electronic component 104. For example, the lid body 106 has a quadrilateral shape in plan view, a size of 10 mm×10 mm to 50 mm×50 mm, and a thickness of 0.5 mm to 2 mm. Examples of a material for the lid body 106 include a metal material, such as iron, copper, nickel, chromium, cobalt, molybdenum, or tungsten, or an alloy combining multiple materials among these metal materials. By application of metalworking such as rolling processing or punching processing to an ingot of such a metal material, the metal member which configures the lid body 106 can be fabricated.

The seal ring 105 has a function to bond the lid body 106 and the frame body 103. The seal ring 105 is positioned on the frame body 103 to surround the electronic component 104 in plan view. Examples of a material for the seal ring 105 include a metal material, such as iron, copper, silver, nickel, chromium, cobalt, molybdenum, or tungsten, or an alloy combining multiple materials among these metal materials. Note that in a case of not providing the seal ring 105 on the frame body 103, the lid body 106 may be bonded via, for example, a bonding material, such as solder, a brazing material, glass, or a resin adhesive material.

Note that the present disclosure is not limited to the embodiments and examples described above, and can variously be changed without departing from the spirit of the present disclosure.

Furthermore, various combinations of the feature parts in the embodiments are not limited to the examples in the embodiments described above, and the respective feature parts can be combined together.

### INDUSTRIAL APPLICABILITY

The present disclosure is applicable to a wiring board, an electronic component mounting package using a wiring board, and an electronic module.

### REFERENCE SIGNS

1 first insulating layer
11 first upper surface
12 first lower surface
2 second insulating layer
21 second upper surface
211 first opening part
211a first linear portion
211b first arc portion
211c second arc portion
211d first recess portion
W211 first opening part width
212 second opening part
212d second recess portion
W212 second opening part width
22 second lower surface
23 cutout portion
3 third insulating layer
51 first ground conductor line
511 first ground conductor film
W51 first ground conductor line width
52 second ground conductor line
521 second ground conductor film
W52 second ground conductor line width
53 signal line
W53 signal line width
6 ground conductor layer
8 external substrate
81 insulating substrate
82 signal transmission line
83 third ground conductor line
84 connection conductor
L1 first gap
L2 second gap
L3 third gap
L4 fourth gap
L5 fifth gap
L211 sixth gap
L7 seventh gap
F bonding material
10 electronic module
100 electronic component mounting package
101a-b wiring board
102 substrate
103 frame body
104 electronic component
105 seal ring
106 lid body

1. A wiring board comprising:
a first insulating layer comprising a first upper surface and a first lower surface;
a second insulating layer positioned on the first insulating layer and comprising a second upper surface, a second lower surface, and one or more first opening parts each comprising an opening at the second upper surface;
a signal line positioned on the second upper surface; and
a first ground conductor line positioned on the second upper surface and extending along the signal line with a first gap between the signal line and the first ground conductor line, wherein
when seen in plan view, at least one of the one or more first opening parts is positioned between the signal line and the first ground conductor line and is in contact with the first ground conductor line.

2. The wiring board according to claim 1, wherein the first opening part is positioned with a second gap between the signal line and the first opening part.

3. The wiring board according to claim 1, further comprising
a second ground conductor line positioned on the second upper surface and extending along the signal line with a third gap between the signal line and the second ground conductor line, wherein
the second ground conductor line is positioned at a side opposite from the first ground conductor line with the signal line interposed between the second ground conductor line and the first ground conductor line.

4. The wiring board according to claim 3, wherein
the second insulating layer further comprises one or more second opening parts each comprising an opening at the second upper surface, and
when seen in plan view, at least one of the one or more second opening parts is positioned between the signal line and the second ground conductor line and is in contact with the second ground conductor line.

5. The wiring board according to claim 4, wherein the second opening part is positioned with a fourth gap between the signal line and the second opening part.

6. The wiring board according to claim 1, wherein
the first opening part comprises a first recess portion positioned at an inner circumferential surface of the first opening part and in contact with the first ground conductor line, and
the first opening part comprises a first ground conductor film provided on an inner circumferential surface of the first recess portion and continuing to the first ground conductor line.

7. The wiring board according to claim 6, wherein
when seen in plan view, the first opening part comprises multiple first recess portions positioned with a gap therebetween, and
the gap is half or less than half of a signal wavelength λ transmitted through the signal line.

8. The wiring board according to claim 6, wherein
when seen in plan view, the first opening part comprises an oval-shaped part comprising an arc portion and a linear portion, and
when seen in plan view, the first recess portion is positioned between the arc portion and the linear portion.

9. The wiring board according to claim 2, wherein the second gap is equal to or less than a length of the first opening part in a direction perpendicular to a direction in which the signal line extends.

10. The wiring board according to claim 1, wherein the first gap is equal to or greater than a length of the signal line in a direction perpendicular to a direction in which the signal line extends.

11. The wiring board according to claim 1, wherein a length of the signal line is equal to or less than a length of the first opening part in a direction perpendicular to a direction in which the signal line extends.

12. The wiring board according to claim 1, wherein a length of the first opening part is greater than a length of the signal line and less than a length of the first ground conductor line in a direction perpendicular to a direction in which the signal line extends.

13. The wiring board according to claim 4, further comprising
a ground conductor layer between the first insulating layer and the second insulating layer, wherein
the ground conductor layer is exposed at a lower surface of the first opening part and/or a lower surface of the second opening part.

14. An electronic component mounting package comprising:
a substrate;
a frame body bonded to an upper surface of the substrate; and
the wiring board according to claim 1, the wiring board being fixed to the frame body.

15. An electronic component mounting package comprising:
a substrate;
a frame body bonded to an upper surface of the substrate;
the wiring board according to claim 6, the wiring board being fixed to the frame body; and
an external substrate connected to the signal line and the first ground conductor line and comprising a third ground conductor line, wherein
when seen in plan view, the third ground conductor line overlaps at least a part of the first recess portion.

16. An electronic module comprising:
the electronic component mounting package according to claim 14;
an electronic component positioned on the upper surface of the substrate and electrically connected to the wiring board of the electronic component mounting package; and
a lid body positioned on the frame body and covering an internal portion of the electronic component mounting package.
